(19) United States
(12) Patent Application Publication
(10) Pub. No.: US 2014/0175537 A1
(43) Pub. Date: Jun. 26, 2014

(54) SEMICONDUCTOR APPARATUS AND FABRICATION METHOD THEREOF

(71) Applicant: SK HYNIX INC., Gyeonggi-do (KR)

(72) Inventors: Min Yong LEE, Gyeonggi-do (KR); Jin Ku LEE, Gyeonggi-do (KR); Jong Chul LEE, Gyeonggi-do (KR)

(73) Assignee: SK HYNIX INC., Gyeonggi-do (KR)

(21) Appl. No.: 13/845,693

(22) Filed: Mar. 18, 2013

(30) Foreign Application Priority Data
Dec. 26, 2012 (KR) 10-2012-0153455

(51) Int. Cl. H01L 29/78; H01L 29/66

(52) U.S. Cl. CPC H01L 29/7827; H01L 29/66666
USPC 257/329; 438/268

(57) ABSTRACT

The semiconductor apparatus includes a semiconductor substrate, an insulating layer formed in the semiconductor substrate to be spaced from a surface of the semiconductor substrate by a predetermined depth and formed to extend to a first direction to have a predetermined width, and an active region formed to be in contact with the semiconductor substrate below the insulating layer through a source post that is formed to vertically penetrate a predetermined portion of the insulating layer, and formed on the insulating layer and the source post to extend to the first direction to have a predetermined width.

### CROSS-REFERENCES TO RELATED APPLICATION

The present application claims priority under 35 U.S.C. 119(a) to Korean application number 10-2012-0153455, filed on Dec. 26, 2012, in the Korean Intellectual Property Office, which is incorporated herein by reference in its entirety.

### BACKGROUND OF THE INVENTION

1. Technical Field

The inventive concept relates to a semiconductor integrated apparatus, and more particularly, to a semiconductor apparatus and a fabrication method thereof.

2. Related Art

Various researches on improvement of integration density in semiconductor memory apparatuses have been progressed. As an example, there are vertical diodes or vertical transistors.

In vertical switching devices, pillars have to be formed to have a sufficient thickness to improve off-current characteristic or an effective channel length. However, the high height of the pillar may cause an aspect ratio to be increased so that the process of forming the device may have difficulty and leaning of the pillar occurs.

Thus, horizontal channel transistors have been suggested and will be described with reference FIGS. 1 to 7B.

FIGS. 1 to 7B are cross-sectional views of a semiconductor device illustrating a method of fabricating a general semiconductor memory apparatus.

First, as illustrated in FIG. 1, a common source region 103 having a predetermined depth is formed in an upper surface of a semiconductor substrate 101. The common source region 103 may be formed, for example, through N⁺ type impurity implantation. Further, the common source region 103 may be formed after an active region is formed in a subsequent process.

Subsequently, a sacrificial layer 105 having a predetermined thickness and a first semiconductor layer 107 having a predetermined thickness are sequentially formed on the semiconductor substrate 101 including the common source region 103. The sacrificial layer 105 and the first semiconductor layer 107 includes semiconductor material layers having different etch selectivities from each other. For example, the sacrificial layer 105 may include silicon germanium (SiGe) and the first semiconductor layer 107 may include silicon (Si). Both of the sacrificial layer 105 and the first semiconductor layer 107 may be formed through an epitaxial growth method to have a perfect crystalline state.

As illustrated in FIG. 2, a photoresist pattern (not shown) is formed on a predetermined region of the first semiconductor layer 107, and the first semiconductor layer 107 and the sacrificial layer 105 are patterned in the same shape as the photoresist pattern to form a hole 109 exposing a surface of the common source region 103.

A heat treatment is performed after the hole 109 is formed, and thus the first semiconductor layer 107 is flowed and a second semiconductor layer 111 filling the hole 109 is formed as illustrated in FIG. 3.

After the second semiconductor layer 111 is formed, a hard mask (not shown) is formed in a direction (the same direction as a direction of the device illustrated in FIG. 3) perpendicular to a formation direction of a gate line to be formed in a subsequent process, and the second semiconductor layer 111 and the sacrificial layer 105 are patterned to confine an active region. FIG. 4A illustrates a state in which an active region ACT is confined in an extending direction of the active region and FIG. 4B illustrates a state in which the active region ACT is confined in a direction perpendicular to the extending direction of the active region.

As described above, the common source region may be formed after the confining of the active region.

When an active region ACT is confined, as illustrated in FIGS. 4A and 48, the sacrificial layer 105 is removed along the exposed surface. As illustrated in FIGS. 5A and 5B, an insulating layer 113 is formed in a space from which the sacrificial layer 105 is removed and is recessed to a predetermined height to form a local silicon-on-insulator (SOI) structure.

The semiconductor substrate as illustrated in FIGS. 5A and 5B may be referred to as a local SOI substrate or a local SOI wafer.

Subsequently, a gate structure, that is, a word line is to be formed on the active region ACT. A cleaning process is performed as a pre-processing process for the gate structure formation.

FIG. 6 illustrates an SOI substrate after the cleaning process. It may be seen from FIG. 6 that the insulating layer 113 is lost in the cleaning process as indicated by “A” and an upper surface of the semiconductor substrate 101 is exposed.

Subsequently, as illustrated in FIGS. 7A and 7B, when a word line 115 is formed and a source region S and a drain region D are formed, the word line 115 comes in contact with the semiconductor substrate 101 in a lost portion of the insulating layer 113 and an undesired current path may be formed through the contact portion.

That is, the active region ACT on the insulating layer 113 serves as a drain D. When the current path is formed toward the semiconductor substrate 101 through the drain D, operation fail may occur and fabrication yield of the device may be degraded.

### SUMMARY

According to one aspect of an exemplary embodiment of the present invention, there is provided a semiconductor apparatus. The semiconductor apparatus may include a semiconductor substrate, an insulating layer formed in the semiconductor substrate to be spaced from a surface of the semiconductor substrate by a predetermined depth and formed to extend to a first direction to have a predetermined width, and an active region formed to be in contact with the semiconductor substrate below the insulating layer through a source post that is formed to vertically penetrate a predetermined portion of the insulating layer, and formed on the insulating layer and the source post to extend to the first direction to have a predetermined width.

According to another aspect of an exemplary embodiment of the present invention, there is provided a method of fabricating a semiconductor apparatus. The method may include forming an insulating layer in a semiconductor substrate to be spaced from a surface of the semiconductor substrate by a predetermined depth, thereby confining a first semiconductor layer on the insulating layer, patterning predetermined portions of the first semiconductor layer and the insulating layer to expose the surface of the semiconductor substrate below the insulating layer, forming a semiconductor layer burying the patterned portions using the first semiconductor layer, and patterning the semiconductor layer burying the patterned portion and the remaining insulating layer to extend to the first direction to form an active region.

These and other features, aspects, and embodiments are described below in the section entitled “DETAILED DESCRIPTION”.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIGS. 1 to 7B are cross-sectional views of a semiconductor device illustrating a method of fabricating a general high-integration semiconductor memory apparatus;

FIGS. 8 to 11B are cross-sectional views of a semiconductor device illustrating a method of fabricating a semiconductor memory apparatus according to an exemplary embodiment of the inventive concept; and

FIGS. 12 to 15 are cross-sectional views of a semiconductor device illustrating a method of fabricating a semiconductor memory apparatus applying the inventive concept.

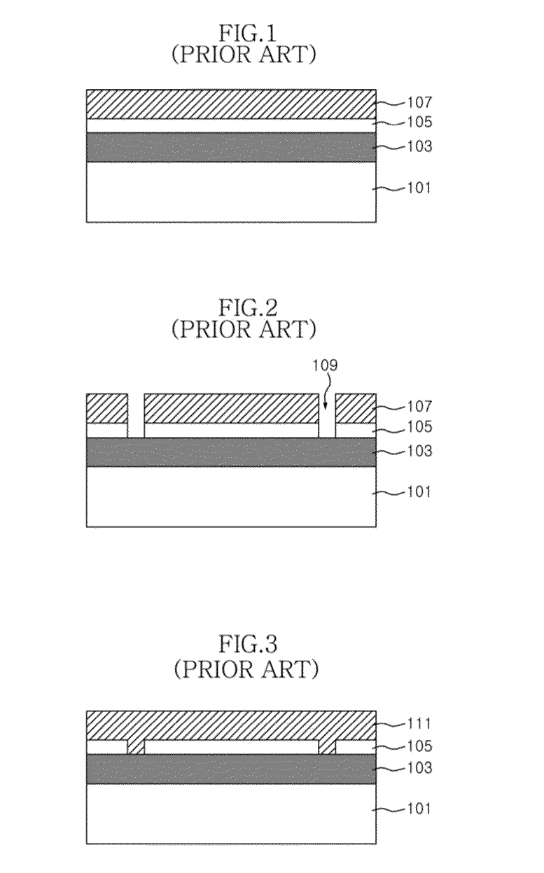

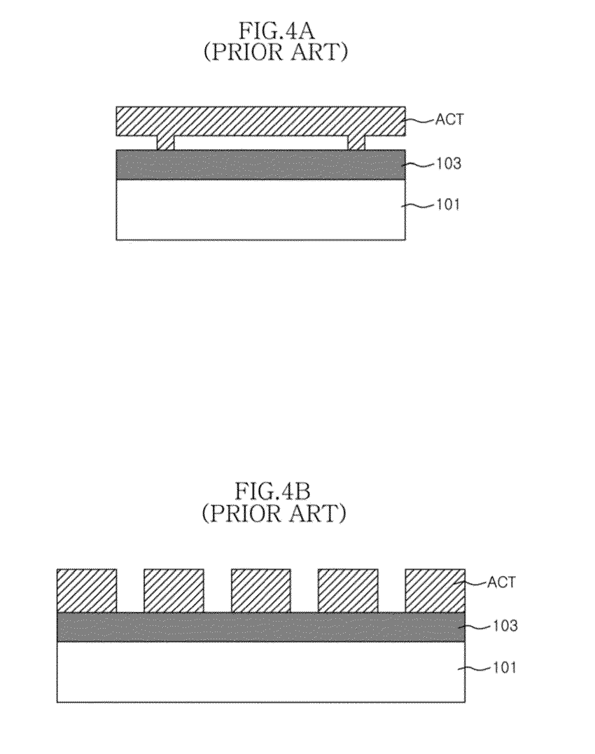

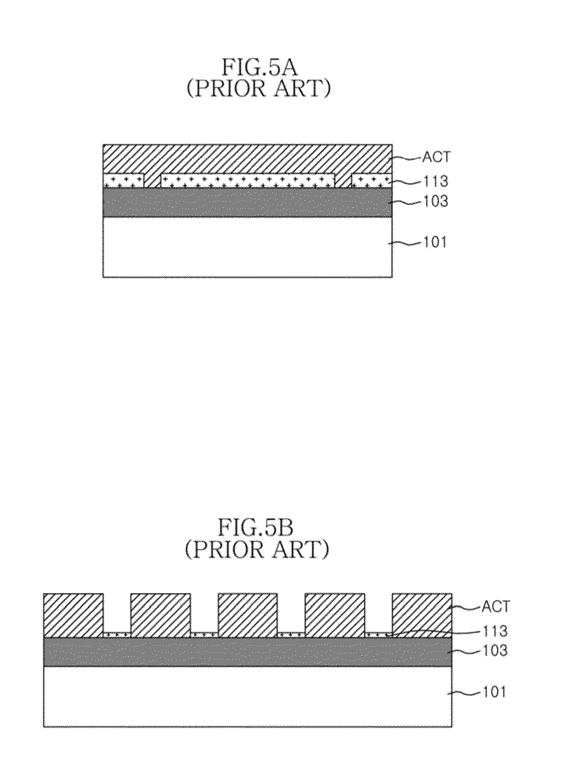

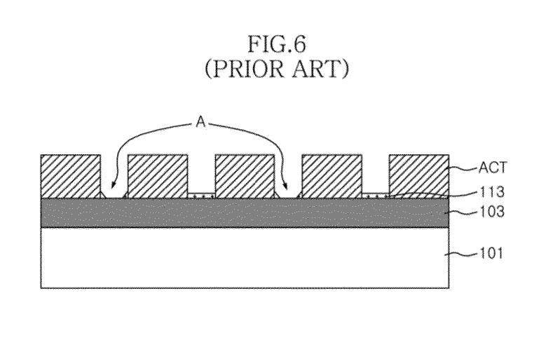

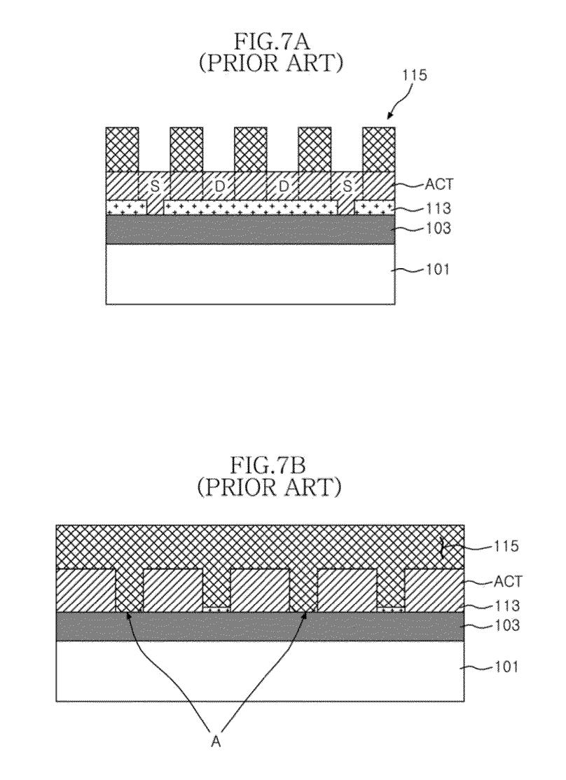

### DETAILED DESCRIPTION

Hereinafter, exemplary embodiments will be described in greater detail with reference to the accompanying drawings.

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may be to include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other or substrate, or intervening layers may also be present.

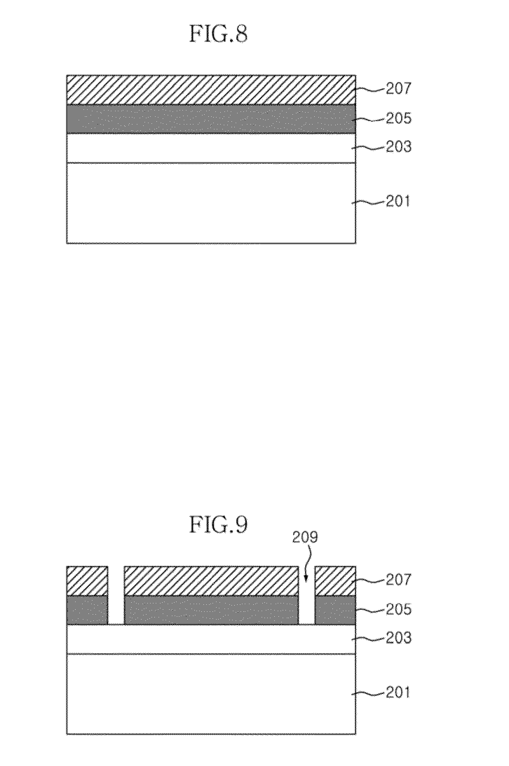

FIGS. 8 to 11B are cross-sectional views of a semiconductor device illustrating a method of fabricating a semiconductor memory apparatus according to an exemplary embodiment of the inventive concept.

Referring to FIG. 8, an insulating layer 205 is formed in a semiconductor substrate 201 to be spaced from a surface of the semiconductor substrate 201 by a predetermined depth.

The insulating layer 205 may be formed by implanting nitrogen ions into the semiconductor substrate 201 to a predetermined depth and by performing heat treatment on the semiconductor substrate. In this case, the insulating layer 205 may be a silicon nitride (SiₓN_{y}) layer. In one exemplary embodiment, the insulating layer 205 may be formed by implanting the nitrogen ions into a portion is of the semiconductor substrate 201, spaced by, example, 600 to 1500 Å from the surface of the semiconductor substrate 201 with an energy of, for example, 20 to 60 KeV. Further, a nitrogen ion implantation angle may be in a range of 0 to 9 degrees. Further, the heat-treatment process may be performed at a temperature of 800 to 1200° C. for several seconds to several minutes using rapid thermal annealing (RTA), performed at a temperature of 800 to 1400° C. for several microseconds to several seconds using fast linear annealing (FLA), performed at a temperature of 800 to 1400° C. for several nanoseconds to several microseconds using laser spike annealing (LSA), or performed at a temperature of 800 to 1400° C. for several minutes to several tens of hours using a furnace.

Further, a concentration of the nitrogen ions may be controlled in a range of 1E12 to 1E17 atoms/cm³ so that a thickness of the insulating layer 205 finally generated after the heat-treatment process becomes 20 to 1000 Å.

The semiconductor substrate below the insulating layer 205 may serve as the first semiconductor layer 207 and a common source region 203 may be formed below the insulating layer 205 before or after the forming of the insulating layer 205.

As illustrated in FIG. 9, a photoresist pattern (not shown) is formed on the first semiconductor layer 207, and the first semiconductor layer 207 and the insulating layer 205 are patterned in the same shape as the photoresist pattern to expose a surface of the semiconductor substrate 201 or a surface of the common source region 203. Therefore, a source post formation region 209 is formed.

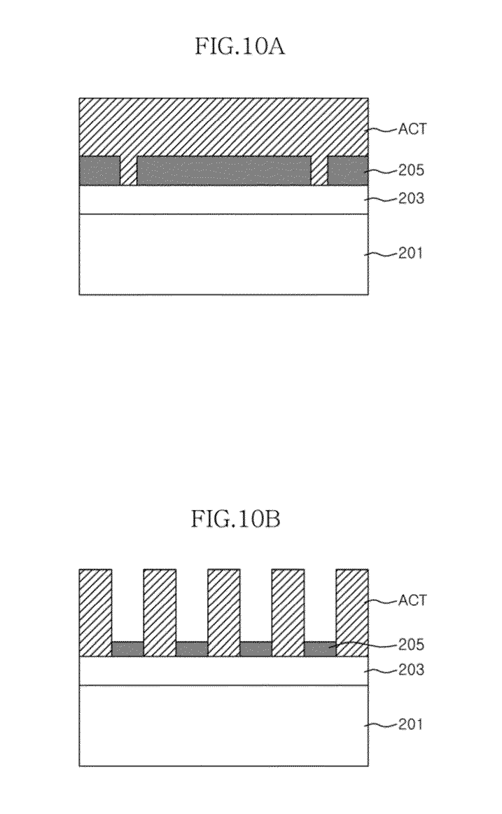

After the source post formation region 209 is formed, cleaning process may be performed on the exposed surface. As illustrated in FIGS. 10A and 10B, a second semiconductor layer is formed to a predetermined thickness based on the first semiconductor Payer 207 to entirely cover the insulating layer 205. The second semiconductor layer is patterned to extend to a first direction as illustrated in FIG. 10A to confine an active region ACT. FIG. 10B illustrates a cross-section view in a direction perpendicular to the first direction. A portion of the active region ACT illustrated in FIG. 10A, which is in contact with the semiconductor substrate, serves as a source post.

When the active region ACT is formed, an etching process is performed using the insulating layer as an etch stop layer. Therefore, a subsequent process, that is, a cleaning process and a gate structure formation process may be performed in a state in which the insulating layer 205 having a sufficient thickness remains on the semiconductor substrate 201.

The semiconductor apparatus formed through the above-described process may include a semiconductor substrate 201, the insulating layer 205 formed in the semiconductor substrate 201 to be spaced from the surface of the semiconductor substrate 201 by a predetermined depth and formed to extend to the first direction and to have a predetermined depth, and the active region ACT formed to be in contact with the semiconductor substrate 201 below the insulating layer 205 through a source post formed to vertically penetrate a predetermined portion of the insulating layer 205 and formed on the insulating layer 205 and the source post to extend to the first direction and to have a predetermined width.

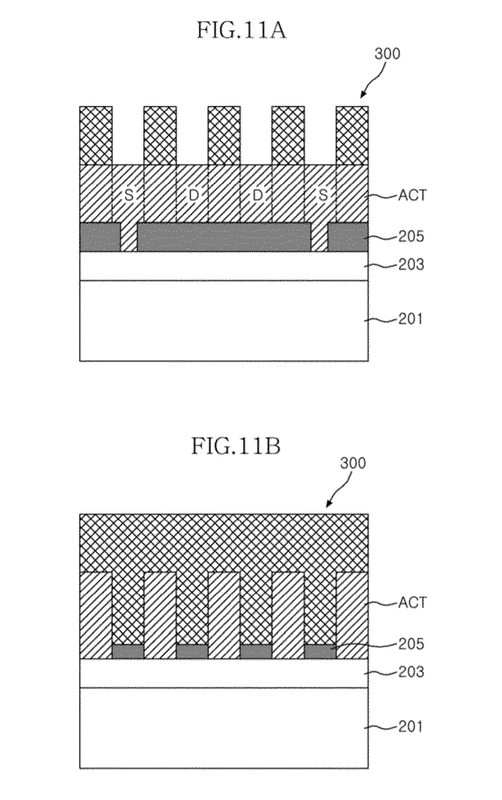

As illustrated in FIGS. 11A and 118, a gate structure 300 is formed on the active region ACT to a direction perpendicular to the active region ACT to cover a top and sidewall of the active region ACT. The gate structure 300 may have a stacked structure of a gate insulating layer, a gate conductive layer, a barrier conductive layer, and a hard mask.

As described above, in the exemplary embodiment, the insulating layer for an SOI structure is previously formed in the semiconductor substrate through ion implantation such as nitrogen. Therefore, the processes of forming a second semiconductor layer, removing a bottom structure, and burying an insulating layer again are removed. Since subsequent processes are performed in a state in which the insulating layer 205 is formed in the semiconductor substrate 201 below the first semiconductor layer 207, a fabrication process becomes simple.

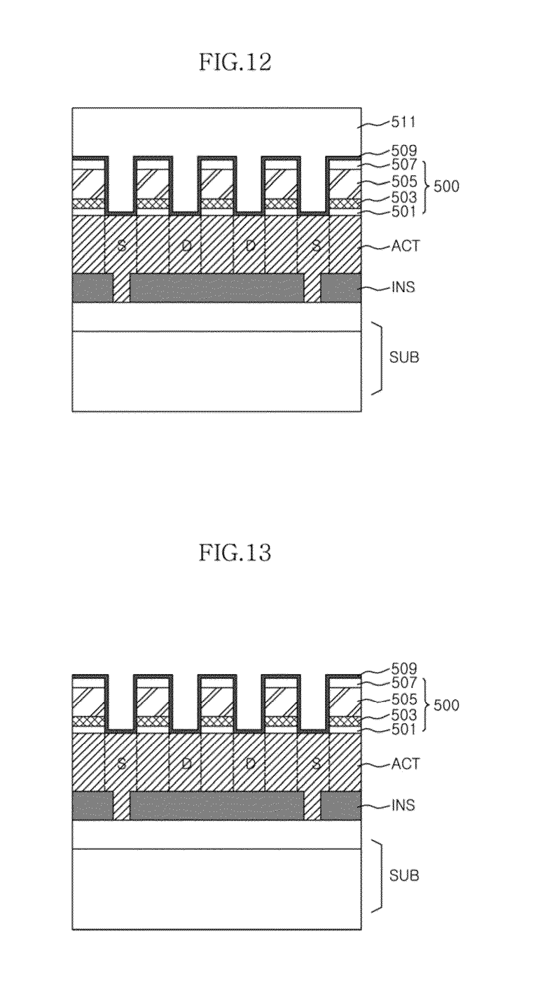

Through the method described with reference to FIGS. 8 to 11, after the SOI substrate (wafer) is formed, a horizontal channel transistor may be formed and a semiconductor memory apparatus adopting the horizontal channel transistor will be described with reference to FIGS. 12 to 15.

FIGS. 12 to 15 are cross-sectional views of a semiconductor device illustrating a method of fabricating a semiconductor memory apparatus to which the inventive concept is applied.

When the common source region 203 is not formed before or after forming the insulating layer 205, the common source region may be formed after the active region ACT is formed through the above-described method.

FIG. 12 illustrates a state in which the active region ACT is formed on a semiconductor substrate SUB in which the common source region is formed.

Subsequently, referring to FIG. 12, after the active region is confined, a gate insulating layer 501 is formed on an exposed surface of the active region ACT, and a gate conductive layer 503, a barrier conductive layer 505, and a hard mask 507 are sequentially formed on the gate insulating layer 501. The hard mask 507, barrier conductive layer 505, and gate conductive layer 503 are patterned in a line shape to be perpendicular to the active region ACT to form a gate structure 500, that is, a word line 500.

Further, a spacer insulating layer 509 is formed on the semiconductor substrate including the word line 500, and impurities are implanted at both sides of the word line 500 to form a source region S o and a drain region D. An interlayer insulating layer 511 is formed on the semiconductor substrate including the source region S and the drain region D to a predetermined height.

As illustrated in FIG. 13, a photoresist pattern is formed on the interlayer insulating layer 511 between active regions to expose a portion of the interlayer insulating layer 511 corresponding to the active regions ACT, and the exposed interlayer insulating layer 511 is removed. Although not shown in FIG. 13, the interlayer insulating layer 511 remains between the active regions ACT and the photoresist patterns are removed.

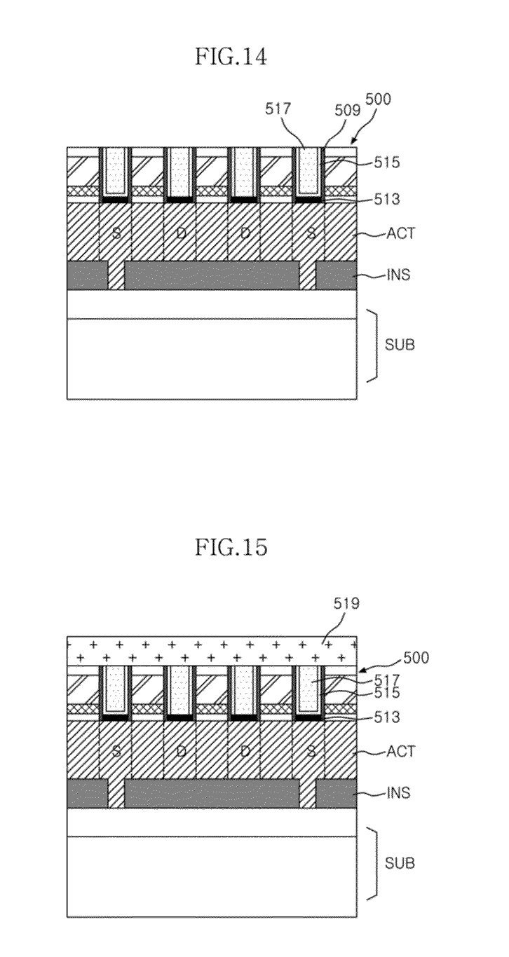

As illustrated in FIG. 14, a spacer etching process is performed on the spacer insulating layer 509 to form a spacer 509 on a sidewall of the word line 500. An electrode 513, an insulating spacer 515, and a data storage material 517 are formed in a space on the source region S between the word lines 500, and in a space on the drain region D between the word lines 500. At this time, the data storage material 517 on the source region S is insulated from the electrode 513 by the insulating spacer 515 and the data storage material 517 on the drain region D is in contact with the electrode 513.

When a unit memory cell is completed by the forming of the data storage material 517, as illustrated in FIG. 15, an interconnection layer electrically connected to the data storage material 517, that is, a bit line 519 is formed.

FIGS. 12 to 15 have illustrated an example of the method of fabricating the horizontal channel transistor. However, the SOI substrate fabricated by the inventive concept is not limited to a bottom structure of the horizontal channel transistor but may be a bottom structure of all applicable semiconductor apparatuses.

The above embodiment of the present invention is illustrative and not limitative. Various alternatives and equivalents are possible. The invention is not limited by the embodiment described herein. Nor is the invention limited to any specific type of semiconductor device. Other additions, subtractions, or modifications are obvious in view of the present disclosure and are intended to fall within the scope of the appended claims.

What is claimed is:

1. A semiconductor apparatus, comprising:
a semiconductor substrate;
an insulating layer formed in the semiconductor substrate to be spaced from a surface of the semiconductor substrate by a predetermined depth, and formed to extend to a first direction to have a predetermined width; and
an active region formed to be in contact with the semiconductor substrate below the insulating layer through a source post that is formed to vertically penetrate a predetermined portion of the insulating layer, and formed on the insulating layer and the source post to extend to the first direction to have a predetermined width.

2. The semiconductor apparatus of claim 1, wherein the insulating layer is a silicon nitride layer.

3. The semiconductor apparatus of claim 1, further comprising a common source region formed below the insulating layer.

4. The semiconductor apparatus of claim 1, further comprising:
a word line formed on the active region to extend to a direction perpendicular to the first direction; and
junction regions formed in the active region at both sides of the word line.

5. The semiconductor apparatus of claim 4, wherein the word line is formed to surround a top and side of the active region.

6. A method of fabricating a semiconductor apparatus, the method comprising:
forming an insulating layer in a semiconductor substrate to be spaced from a surface of the semiconductor substrate by a predetermined depth, thereby confining a first semiconductor layer on the insulating layer;
patterning predetermined portions of the first semiconductor layer and the insulating layer to expose the surface of the semiconductor substrate below the insulating layer;
forming a semiconductor layer burying the patterned portions using the first semiconductor layer; and
patterning the semiconductor layer burying the patterned portion and the remaining insulating layer to extend to the first direction to form an active region.

7. The method of claim 6, wherein the forming an insulating layer includes implanting nitrogen ions into a portion of the semiconductor substrate spaced from the surface of the semiconductor substrate and performing heat treatment on the semiconductor substrate.

8. The method of claim 7, wherein the insulating layer is formed by implanting the nitrogen ions with an energy of 20 to 60 Kev.

9. The method of claim 8 wherein the nitrogen ions are implanted at a degree of 0 to 9.

10. The method of claim 8, wherein the heat treatment is performed at a temperature of 800 to 1200° C. for several seconds to several minutes using rapid thermal annealing (RTA), performed at a temperature of 800 to 1400° C. for several microseconds to several seconds using fast linear annealing (FLA), performed at a temperature of 800 to 1400° C. for several nanoseconds to several microseconds using laser spike annealing (LSA), or performed at a temperature of 800 to 1400° C. for several minutes to several tens of hours using a furnace.

11. The method of claim 8, wherein a concentration of the nitrogen ions is in a range of 1E12 to 1E17 atoms/cm³.

12. The method of claim 6, further comprising forming a word line on the active region to extend to a second direction perpendicular to the first direction.

13. The method of claim 12, wherein he word line is formed to surround a top and side of the active region.

14. The method of claim 12, further comprising, after the forming a word line, implanting impurities into the active region at both sides of the word line to form impurity regions.

15. The method of claim 14, further comprising forming an electrode and a data storage material on the impurity regions.

16. The method of claim 15, wherein one of the impurity regions electrically connected to the semiconductor substrate serves as a source region and the other of the impurity regions in contact with the insulating layer serves as a drain region.

17. The method of claim 6, further comprising, before the forming an insulating layer, forming a common source region to a predetermined depth in the semiconductor substrate below the insulating layer.

18. The method of claim 16, wherein the electrode and the data storage material are formed on the source region and insulated from each other.
